(19) United States
(12) Patent Application Publication
(10) Pub. No.: US 2007/0145468 A1
(43) Pub. Date: Jun. 28, 2007

(54) Quantum dot nonvolatile transistor

(76) Inventors: Amlan Majumdar, Portland, OR (US); Suman Datta, Beaverton, OR (US); Been-Yih Jin, Lake Oswego, OR (US); Mark L. Doczy, Beaverton, OR (US); Robert S. Chau, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/322,089

(22) Filed: Dec. 28, 2005

(51) Int. Cl. H01L 29/788

(52) U.S. Cl. 257/316

(57) ABSTRACT

Some embodiments of the present invention include apparatuses and methods relating to nonvolatile memory transistors.

### TECHNICAL FIELD

Embodiments of the invention relate to nonvolatile memory technology. In particular, embodiments of the invention relate to quantum dot nonvolatile transistors.

### BACKGROUND

Nonvolatile memory products are able to retain stored information or data without a continuous power source. They may be contrasted with volatile memory components which require a continual memory refresh, and therefore continual power, to retain memory information. Due to their ability to retain data without power (and other attributes), nonvolatile memory products are useful in a variety of applications, such as memory cards, digital cameras, mobile phones, and many others. Nonvolatile transistors are a key component of nonvolatile memory products.

FIG. 1 illustrates a typical nonvolatile memory transistor 100. Transistor 100 includes a substrate 101 having a doped well 102 and isolation regions 103. Isolation regions 103 may electrically isolate transistor 100 from adjacent transistors. Transistor 100 also includes a source 104, a source tip 105, a drain 106, a drain tip 107, and a channel 108. Further, transistor 100 includes a gate stack including a silicon dioxide tunnel dielectric 109, a polysilicon floating gate 110, a silicon dioxide control gate dielectric 111, and a polysilicon control gate 112 between spacers 113.

In operation, transistor 100 may be programmed for memory storage by providing or not providing an electrical charge in polysilicon floating gate 110. For example, the memory state may be 1 or 0 depending on whether electrical charge is stored. The electrical charge may be retained in polysilicon floating gate 110 because polysilicon floating gate 110 is surrounded by insulating materials. To sense the memory state of transistor 100, a voltage is applied to polysilicon control gate 112 and a current may flow from source 104 to drain 106 in response to the supplied voltage depending on whether a charge is stored in polysilicon floating gate 110. The current may then be sensed to reproduce the memory state of transistor 100.

The performance characteristics of nonvolatile memory products may depend directly on the characteristics of the nonvolatile transistors. In particular, it may be advantageous to have nonvolatile transistors that have increased electrical charge retention capability, such that they retain data longer and more efficiently. Further, it may be advantageous to provide nonvolatile transistors that can be scaled to smaller sizes in order to increase the density, complexity, data storage capability, and speed of nonvolatile memory products.

### BRIEF DESCRIPTION OF THE DRAWINGS

The invention is illustrated by way of example and not by way of limitation in the figures of the accompanying drawings, in which the like references indicate similar elements and in which:

FIG. 1 is a cross-sectional view of a prior art nonvolatile memory transistor.

FIG. 2 is a cross-sectional view of a nonvolatile transistor including a floating gate having quantum dots.

FIG. 3A is a cross-sectional view of a partially formed transistor including a doped well, isolation regions, source/drain regions, a gate stack, spacers, and an interlayer dielectric.

FIG. 3B is a view similar to FIG. 3A with the gate stack removed to form a trench.

FIG. 3C is a view similar to FIG. 3B with a tunnel dielectric formed in the trench.

FIG. 3D is a view similar to FIG. 3C with a floating gate including quantum dots formed over the tunnel dielectric.

FIG. 3E is a view similar to FIG. 3D with a control gate dielectric formed over the floating gate.

FIG. 3F is a view similar to FIG. 3E with a gate electrode formed over the control gate dielectric.

FIG. 3G is a view similar to FIG. 3F with the interlayer dielectric removed and silicide formed in the source and drain regions.

FIG. 3H is a view similar to FIG. 3G with an interlayer dielectric and electrical contacts to the gate electrode and the silicide portion of the source/drain regions.

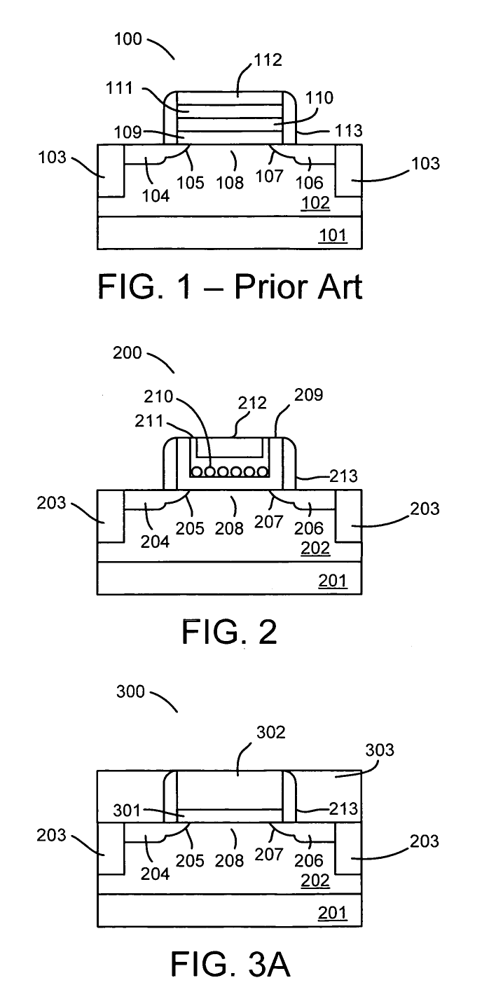

### DETAILED DESCRIPTION

In various embodiments, apparatuses and methods relating to nonvolatile transistors are described. However, various embodiments may be practiced without one or more of the specific details, or with other methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

In nonvolatile transistor applications, it may be desirable to provide floating gates with increased retention capabilities. Further, scaling typical nonvolatile transistors to smaller and smaller dimensions may be difficult for several reasons. For example, further scaling the silicon dioxide tunnel oxide, which is already very thin, may be difficult because any defects in the silicon dioxide tunnel oxide may cause leakage from the floating gate, which would substantially decrease charge retention in the floating gate. Also, not scaling the silicon dioxide tunnel oxide while scaling the other dimensions of the nonvolatile transistor may increase the off-state current of the device and therefore increase stand-by power consumption. Lastly, as transistors are scaled, they may be placed closer together, which may increase floating gate to floating gate capacitive coupling between adjacent transistors. Increased capacitive coupling between transistors may cause disturbances in one transistor while accessing an adjacent transistor. Briefly, the present invention may provide nonvolatile transistors that include floating gates with increased retention capabilities and characteristics that allow for scaling the nonvolatile transistor to smaller dimensions.

FIG. 2 illustrates a nonvolatile transistor 200. Transistor 200 may be in and on a substrate 201, which may include any suitable material or materials such as silicon, germanium, gallium arsenide, indium phosphide, silicon on insulator, or the like. Transistor 200 may be between isolation regions 203 which may electrically isolate adjacent transistors.

Transistor 200 may include a doped well 202, a source 204, a source tip 205, a drain 206, a drain tip 207, and a channel 208. In various embodiments, doped well 202, source 204, source tip 205, drain 206, and drain tip 207 may be formed in substrate 201 and may include dopants that may modify the characteristics of the substrate material. Channel 208 may be a portion of doped well 202 that is between source tip 205 and drain tip 206.

In an embodiment, transistor 200 may be an NMOS (negative channel metal oxide semiconductor) transistor and doped well 202 may be a p-well doped with p-type dopants and source 204, source tip 205, drain 206, and drain tip 207 may be doped with n-type dopants. In another embodiment, transistor 200 may be a PMOS (negative channel metal oxide semiconductor) transistor and doped well 202 may be an n-well doped with n-type dopants and source 204, source tip 205, drain 206, and drain tip 207 may be doped with p-type dopants. In an embodiment, transistor 200 may be a PMOS transistor and source 204 and drain 206 may include raised epitaxial films (not shown) including germanium or silicon germanium in order to provide a compressive strain on channel 208. In an embodiment, NMOS and PMOS transistors may be integrated on the same substrate to form a CMOS (complimentary metal oxide semiconductor) device.

Transistor 200 also includes a gate between spacers 213. Spacers 213 may include any suitable material or materials, such as a nitride or an oxide. The gate may include a tunnel dielectric 209, a quantum dot floating gate 210, a control gate dielectric 211, and a control gate 212. The gate may also be generally referred to as a gate stack or a gate structure.

Tunnel dielectric 209 may provide insulation between channel 208 and quantum dot floating gate 210 and may include any suitable insulating material. In an embodiment, tunnel dielectric 209 may include silicon dioxide. In other embodiments, tunnel dielectric 209 may include a high-k dielectric material, where high-k refers to a dielectric constant (k) greater than the dielectric constant of silicon dioxide, which is about 3.9. In an embodiment, tunnel dielectric may have a dielectric constant greater than about 5. In an embodiment, tunnel dielectric may have a dielectric constant greater than about 10. In another embodiment, tunnel dielectric may have a dielectric constant greater than about 20. In various embodiments, tunnel dielectric 209 may include hafnium silicon oxide, hafnium oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof.

A high-k tunnel dielectric may provide advantageous characteristics for transistor 200. In general, it may be desired to have an increased capacitance between quantum dot floating gate 210 and channel 208. One way to increase the capacitance is to scale, or decrease, the thickness of tunnel dielectric 209. However, decreasing the thickness of tunnel dielectric 209 may increase charge depletion from quantum dot floating gate 210 to channel 208 due to the decreased physical distance between quantum dot floating gate 210 and channel 208, and the greater likelihood of defects or voids in tunnel dielectric 209. A high-k tunnel dielectric 209 may provide similar or greater capacitance at greater physical thickness than silicon dioxide and thereby provide increased capacitance with less charge depletion from the quantum dot floating gate. Further, because a high-k tunnel dielectric 209 may have similar electrical properties at a greater physical thickness, it may be easier to decrease the thickness, enabling scalability of transistor 200.

Tunnel dielectric 209 may be on channel 208 and may extend between spacers 213. In an embodiment, tunnel dielectric 209 may also extend along the sidewalls of spacers 213 such that the sidewalls of spacers 213 are substantially covered as is shown in FIG. 2. In another embodiment, tunnel dielectric 209 may not extend along the sidewalls of spacers 213.

In embodiments where tunnel dielectric 209 extends along the sidewalls of spacers 213, tunnel dielectric 209 may provide for a self-aligned quantum dot floating gate 210. In an embodiment, the distance that tunnel dielectric 209 extends away from the sidewalls of spacers 213 may be about the same as or greater than the distance source tip 205 and drain tip 207 extend beyond spacers 213 and under tunnel dielectric 209. Quantum dot floating gate 210 may then be substantially aligned to channel 208. This alignment may be beneficial because any alignment between quantum dot floating gate 210 and source tip 205 or drain tip 207 may cause charge depletion from quantum dot floating gate 210 into source 204 or drain 205. Self-alignment may also offer the advantage of low parasitic overlap capacitance.

Quantum dot floating gate 210 may provide for electrical charge retention and may include quantum dots of any suitable material or materials. In general, a quantum dot may include any discrete nanocrystal. A quantum dot may include a single material or several materials. Typically, a quantum dot may have dimensions ranging from about 1 nanometer to a few microns. In an embodiment, quantum dot floating gate 210 may include germanium. In another embodiment, quantum dot floating gate 210 may include silicon. In other embodiments, quantum dot floating gate 210 may include boron, aluminum, gallium, indium, thallium, nitrogen, phosphorous, arsenic, antinomy, bismuth, or combinations thereof. The quantum dots may be of any suitable size and any suitable number. In an embodiment, the quantum dots may be about 5 to 40 nm across. In an embodiment, the quantum dots may be about 3 to 10 nm across. In another embodiment, the quantum dots may be about 5 to 15 nm across.

Quantum dot floating gate 210 may provide advantages over typical bulk floating gate materials, such as polysilicon. In an embodiment, quantum dot floating gate 210 may provide increased electrical charge retention capability. Quantum dot floating gate 210 may provide increased electrical charge retention capability due to characteristics of quantum dots including quantum confinement and Coulomb blockade effects. In another embodiment, quantum dot floating gate 210 may provide the advantage that a local defect in tunnel dielectric 209 may deplete the electrical charge of one or few quantum dots instead of the electrical charge of the entirety or a majority of a continuous floating gate material.

Control gate dielectric 211 may electrically insulate quantum dot floating gate 210 and control gate 212, and may include any suitable insulative material or materials. Control gate dielectric 211 may be the same material as tunnel dielectric 209 or it may be different. In an embodiment, control gate dielectric 211 may be a conformal layer over quantum dot floating gate 210. In various embodiments, tunnel dielectric 209 may include silicon dioxide, hafnium silicon oxide, hafnium oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or any combination thereof.

Control gate 212 may provide electrical contact to the gate and may include any suitable conductive material or materials. In an embodiment, control gate 212 may include a metal. In an embodiment, a metal control gate 212 may eliminate polysilicon depletion in the gate structure during operation. In various embodiments, control gate 212 may include hafnium, zirconium, titanium, tantalum, aluminum, their alloys, or their carbides or nitrides. In other embodiments, control gate 212 may include tungsten, molybdenum, rhodium, vanadium, platinum, ruthenium, beryllium, palladium, cobalt, titanium, nickel, copper, tin, aluminum, lead, zinc, alloys, or their silicides.

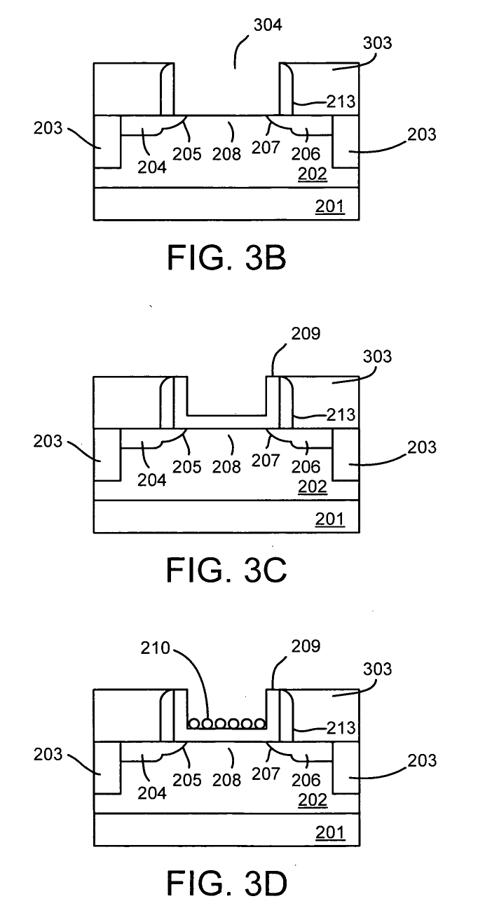

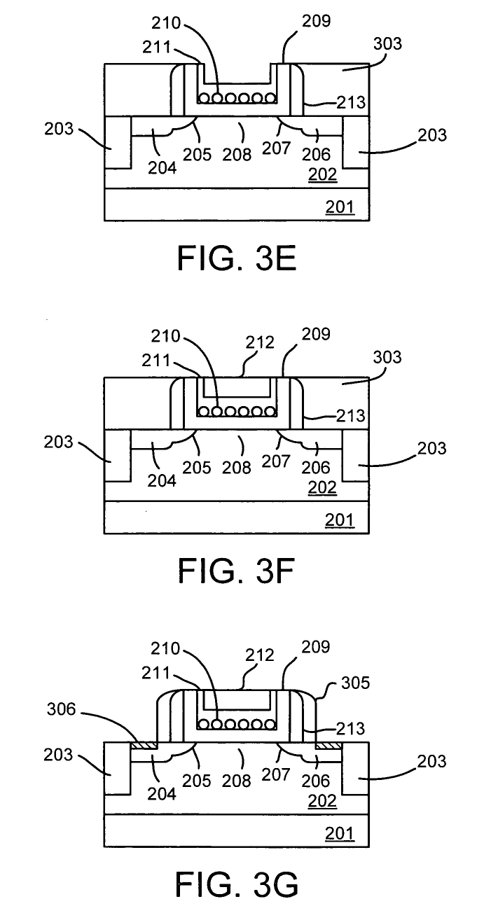

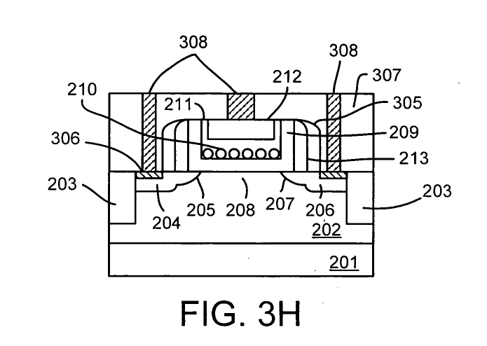

FIGS. 3A-3H illustrate an example method for forming a nonvolatile transistor including a quantum dot floating gate.

As illustrated in FIG. 3A, a transistor 300 may be formed by standard techniques in and on substrate 201. Transistor 300 may include doped well 202, isolation regions 203, source 204, source tip 205, drain 206, drain tip 207, channel 208, and spacers 213 as discussed above. Transistor 300 may also include a gate dielectric 301, a gate electrode 302, and an interlayer dielectric 303. Gate dielectric 301 and gate electrode 302 may be referred to as a gate stack or a gate structure. In an embodiment, gate dielectric 301 may include silicon dioxide and gate electrode 302 may include polysilicon. However, since gate dielectric 301 and gate electrode 302 may be removed and replaced with different gate materials, as is discussed with reference to FIGS. 3B-3F, they may include any suitable sacrificial materials. In an embodiment, the sacrificial gate may include only one suitable material. In other embodiments, the sacrificial gate may include 3 or more materials.

In FIG. 3B, gate dielectric 301 and gate electrode 302 may be removed to form a trench 304. Gate dielectric 301 and gate electrode 302 may be removed by any suitable technique, such as a selective etch process.

As illustrated in FIG. 3C, tunnel dielectric 209 may be formed in trench 214. Tunnel dielectric 209 may be formed by any suitable technique, such as chemical vapor deposition (CVD), physical vapor deposition (PVD), atomic layer deposition (ALD), or the like. In some embodiments, in forming tunnel dielectric 209, a deposited dielectric material may also be formed over interlayer dielectric 303. In such embodiments, the dielectric material over interlayer dielectric 303 may be removed by any suitable technique such as chemical mechanical polishing (CMP) or etching. Tunnel dielectric 209 may include any material or materials as discussed above with reference to FIG. 2. In general, tunnel dielectric 209 may be referred to as a dielectric layer, a dielectric material, or a dielectric.

As illustrated in FIG. 3D, quantum dot floating gate 210 may be formed over tunnel dielectric 209. Quantum dot floating gate 210 may be formed by any suitable technique. In an embodiment, quantum dot floating gate 210 may be formed by a CVD process. In another embodiment, quantum dot floating gate 210 may be formed by an epitaxial growth process. In an embodiment, surface tension may cause a deposited or epitaxially grown material to relax and ball up to form quantum dots. In an embodiment, a lattice spacing mismatch between the material of tunnel dielectric 209 and the material of the quantum dots may cause the formation of the quantum dots. In an embodiment, the lattice spacing mismatch may be greater than about 4 percent. In general, quantum dot floating gate 210 may be referred to as a quantum dot layer or quantum dots.

In some embodiments, in forming quantum dot floating gate 210, quantum dots may also be formed over interlayer dielectric 303 or a previously deposited material. In such embodiments, the quantum dots over interlayer dielectric 303 or the previously deposited material may be removed by any suitable technique such as CMP or etching. Quantum dot floating gate 210 may include any material or materials as discussed above with reference to FIG. 2.

Forming quantum dot floating gate 210 in a replacement gate process as illustrated may offer the advantage that the subsequent process flow does not require a high temperature step after the formation of quantum dot floating gate 210. In an embodiment, all of the high temperature process steps that may be required in forming the transistor, such as source and drain activation anneal, may already be complete. A high temperature step, such as an anneal, after forming quantum dot floating gate 210 may relax and deform the quantum dots.

As illustrated in FIG. 3E, control gate dielectric 211 may be formed over quantum dot floating gate 210. Control gate dielectric 211 may be formed by any suitable technique, such as CVD, PVD, ALD, or the like. In an embodiment, control gate dielectric 211 may be formed in a conformal manner over quantum dot floating gate 210, such that control gate dielectric 211 conforms to quantum dot floating gate 210 and leaves quantum dot floating gate 210 relatively unchanged. In another embodiment, control gate dielectric 211 may be formed in a conformal manner using ALD. In some embodiments, in forming control gate dielectric 211, dielectric material may also be formed over interlayer dielectric 303 or previously deposited materials. Control gate dielectric 211 may include any material or materials as discussed above with reference to FIG. 2. In such embodiments, the dielectric material over interlayer dielectric 303 or previously deposited materials may be subsequently removed by any suitable technique. Control gate dielectric 211 may be generally referred to as a dielectric layer or a dielectric.

As illustrated in FIG. 3F, control gate 212 may be formed over control gate dielectric 211. Control gate 212 may be formed by any suitable technique, such as CVD, PVD, ALD, electroplating or the like. In some embodiments, in forming control gate 212, the deposited material may also be formed over interlayer dielectric 303 or previously deposited materials. In such embodiments, the dielectric material over interlayer dielectric 303 or previously deposited materials may be removed by any suitable technique such as an etch step or CMP. Control gate 212 may include any material or materials as discussed above with reference to FIG. 2. Generally, control gate 212 may be referred to as a conductor or a conductive layer or a conductive plug.

As illustrated in FIG. 3G, interlayer dielectric 303 and any materials previously deposited over interlayer dielectric 303 may be removed. The materials may be removed by any suitable techniques, such as CMP, wet etch, dry etch, or the like. Further, second spacers 305 and silicide regions 306 may be formed by any suitable techniques. Second spacers 305 may include any suitable materials, such as a nitride or an oxide. Silicide regions 306 may also include any suitable material. In an embodiment, silicide regions 306 may include a metal. In another embodiment, silicide regions 305 may include nickel.

As illustrated in FIG. 3H, an interlayer dielectric 307 may be deposited and contacts 308 may be formed. Interlayer dielectric 307 may be formed by any suitable technique and may include any suitable insulative material or materials. In an embodiment, forming interlayer dielectric 307 may include a deposition step and a CMP step. Contacts 308 may also be formed by any suitable technique, such as lithography, etch, deposition, and planar techniques. Contacts 308 may include any suitable conductive material. In some embodiments, contacts 308 may include a metal. Contacts 308 may provide electrical contact to source 204, drain 206, and control gate 212.

Reference throughout this specification to “one embodiment” or “an embodiment” means that a particular feature, structure, material, or characteristic described in connection with the embodiment is included in at least one embodiment of the invention. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. A transistor gate comprising:
a high-k tunnel dielectric;
a floating gate including quantum dots on the tunnel dielectric;
a control gate dielectric on the floating gate; and
a control gate on the control gate dielectric.

2. The transistor gate of claim 1, wherein the tunnel dielectric comprises at least one of hafnium silicon oxide, hafnium oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

3. The transistor gate of claim 1, wherein the control gate comprises a metal.

4. The transistor gate of claim 1, wherein the control gate comprises at least one of hafnium, zirconium, titanium, tantalum, or aluminum, or their nitrides or carbides.

5. The transistor gate of claim 1, wherein the control gate comprises at least one of tungsten, molybdenum, rhodium, vanadium, platinum, ruthenium, beryllium, palladium, cobalt, titanium, nickel, copper, tin, aluminum, lead, or zinc.

6. The transistor gate of claim 1, wherein the quantum dots comprise germanium.

7. The transistor gate of claim 1, wherein the quantum dots comprise at least one of boron, aluminum, gallium, indium, thallium, nitrogen, phosphorous, arsenic, antinomy, or bismuth.

8. A transistor comprising:
a channel between a source region and a drain region;
a gate over the channel and between spacers, wherein the gate includes a tunnel dielectric on the channel and extending along sidewalls of the spacers, a quantum dot floating gate on a portion of the tunnel dielectric, a control gate dielectric on the quantum dot floating gate, and a control gate on the control gate dielectric.

9. The transistor of claim 8, wherein the quantum dot floating gate comprises germanium.

10. The transistor of claim 8, wherein the tunnel dielectric comprises a high-k dielectric.

11. The transistor of claim 8, wherein the tunnel dielectric comprises at least one of hafnium silicon oxide, hafnium oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

12. The transistor of claim 8, wherein the control gate comprises a metal.

13. The transistor of claim 8, wherein the control gate dielectric comprises a high-k dielectric.

14. The transistor of claim 8, wherein the gate is over a portion of the source region and a portion of the drain region and wherein the quantum dot floating gate is self-aligned to the channel.

15. The transistor of claim 14, wherein the portion of the source region comprises a source tip and the portion of the drain region comprises a drain tip.

16. The transistor of claim 8, wherein the gate is over a portion of the source region and wherein the dielectric along the spacer over the source region extends away from the spacer farther than the source region extends under the gate.

17. A method for forming a nonvolatile transistor comprising:
forming a transistor including a sacrificial gate, wherein the sacrificial gate is between at least two spacers;
removing the sacrificial gate to form a trench;
forming a high-k dielectric layer in the trench;
forming quantum dots over the high-k dielectric layer;
forming a second dielectric layer over the quantum dots; and
forming a conductor over the second dielectric layer.

18. The method of claim 17, wherein the transistor includes a channel between a source region and a drain region and wherein the sacrificial gate is on the channel, a portion of the source region, and a portion of the drain region.

19. The method of claim 18, wherein forming the quantum dots comprises forming the quantum dots such that they are self-aligned to the channel.

20. The method of claim 17, wherein the high-k dielectric layer comprises at least one of hafnium silicon oxide, hafnium oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

21. The method of claim 17, wherein the quantum dots comprise a first material and the high-k dielectric layer comprises a second material, and wherein the first material and the second material have a lattice spacing difference.

22. The method of claim 21, wherein the lattice spacing difference is greater than about 4%.

23. The method of claim 17, wherein forming the quantum dots comprise at least one of germanium, boron, aluminum, gallium, indium, thallium, nitrogen, phosphorous, arsenic, antinomy, or bismuth.

24. The method of claim 17, wherein forming the second dielectric layer comprises forming a conformal dielectric layer by atomic layer deposition.

25. The method of claim 17, wherein the second dielectric comprises a high-k dielectric.

26. The method of claim 17, wherein the high-k dielectric layer comprises a tunnel dielectric, the quantum dots comprise a floating gate, the second dielectric layer comprises a control gate dielectric, and the conductor comprises a control gate.
